(19) United States
(12) Patent Application Publication
(10) Pub. No.: US 2025/0294670 A1
(43) Pub. Date: Sep. 18, 2025

(54) ELECTRONIC DEVICE

(71) Applicant: Advanced Semiconductor Engineering, Inc., Kaohsiung (TW)

(72) Inventor: Wei-Hao CHANG, Kaohsiung (TW)

(73) Assignee: Advanced Semiconductor Engineering, Inc., Kaohsiung (TW)

(21) Appl. No.: 18/605,706

(22) Filed: Mar. 14, 2024

(51) Int. Cl. H05K 1/02; H05K 3/28; H05K 5/00

(52) U.S. Cl. CPC H05K 1/028; H05K 3/28; H05K 5/003; H05K 2203/1305

(57) ABSTRACT

An electronic device is provided. The electronic device includes a flexible circuit structure, a package structure, and a flexible encapsulation layer. The package structure is supported by the flexible circuit structure and includes a first stress-dissipating part at a periphery region of the package structure. The flexible encapsulation layer encapsulates the package structure.

### BACKGROUND

### 1. Field of the Disclosure

The present disclosure relates to an electronic device and a method of manufacturing an electronic device.

### 2. Description of the Related Art

The bending test, which includes twisting or rolling, provides a reliability index for a wearable device. During this test, attention is given to potential cracks that may occur in a flexible carrier.

### SUMMARY

In some embodiments, an electronic device includes a flexible circuit structure, package structure, and a flexible encapsulation layer. The package structure is supported by the flexible circuit structure and includes a first stress-dissipating part at a periphery region of the package structure. The flexible encapsulation layer encapsulates the package structure.

In some embodiments, an electronic device includes a first region, a second region, a third region, and a package structure. The second region is distant from the first region. The package structure is located in the third region between the first region and the second region. The package structure is configured to allow the first region and the second region bending toward the package structure in different extents.

In some embodiments, an electronic device includes a circuit structure and a package structure. The package structure is disposed above the circuit structure and includes a first periphery portion configured to dissipate stress between the package structure and the circuit structure.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-section of an electronic device according to some embodiments of the present disclosure.

FIG. 1A is a bottom view of a package structure of an electronic device according to some embodiments of the present disclosure.

FIG. 1B is an enlarged view of a periphery region of a package structure in FIG. 1.

FIG. 1C is a cross-section of an electronic device under a bending test according to some embodiments of the present disclosure.

FIG. 2 is a cross-section of an electronic device according to some embodiments of the present disclosure.

FIG. 2A is a bottom view of a package structure of an electronic device according to some embodiments of the present disclosure.

FIG. 3 is a cross-section of an electronic device according to some embodiments of the present disclosure.

FIG. 4 is a cross-section of an electronic device according to some embodiments of the present disclosure.

FIG. 4A is a cross-section of an electronic device under a bending test according to some embodiments of the present disclosure.

FIG. 5 is a cross-section of an electronic device according to some embodiments of the present disclosure.

FIG. 6 is a cross-section of an electronic device according to some embodiments of the present disclosure.

FIG. 7 is a cross-section of an electronic device according to some embodiments of the present disclosure.

FIG. 8 is a bottom view of an electronic device according to some embodiments of the present disclosure.

FIG. 8A is a perspective view of an electronic device according to some embodiments of the present disclosure.

FIG. 8B is a bottom view of an electronic device under a twisting test according to some embodiments of the present disclosure.

FIG. 8C is a perspective view of an electronic device under a twisting test according to some embodiments of the present disclosure.

FIG. 8C-1 is a side view of an electronic device under a twisting test according to some embodiments of the present disclosure.

FIG. 8D is a cross-section of an electronic device along the line 8D-8D′ in FIG. 8B according to some embodiments of the present disclosure.

FIG. 8E is a cross-section of an electronic device along the line 8E-8E′ in FIG. 8B according to some embodiments of the present disclosure.

FIG. 9A illustrates one or more stages of an example of a method for manufacturing an electronic device according to some embodiments of the present disclosure.

FIG. 9B illustrates one or more stages of an example of a method for manufacturing an electronic device according to some embodiments of the present disclosure.

FIG. 9C illustrates one or more stages of an example of a method for manufacturing an electronic device according to some embodiments of the present disclosure.

FIG. 9D illustrates one or more stages of an example of a method for manufacturing an electronic device according to some embodiments of the present disclosure.

FIG. 9D-1 is an enlarged view of a box B3 in FIG. 9D.

FIG. 9D-2 is another enlarged view of a box B3 in FIG. 9D.

FIG. 9E illustrates one or more stages of an example of a method for manufacturing an electronic device according to some embodiments of the present disclosure.

FIG. 9F illustrates one or more stages of an example of a method for manufacturing an electronic device according to some embodiments of the present disclosure.

FIG. 9G illustrates one or more stages of an example of a method for manufacturing an electronic device according to some embodiments of the present disclosure.

FIG. 9H illustrates one or more stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

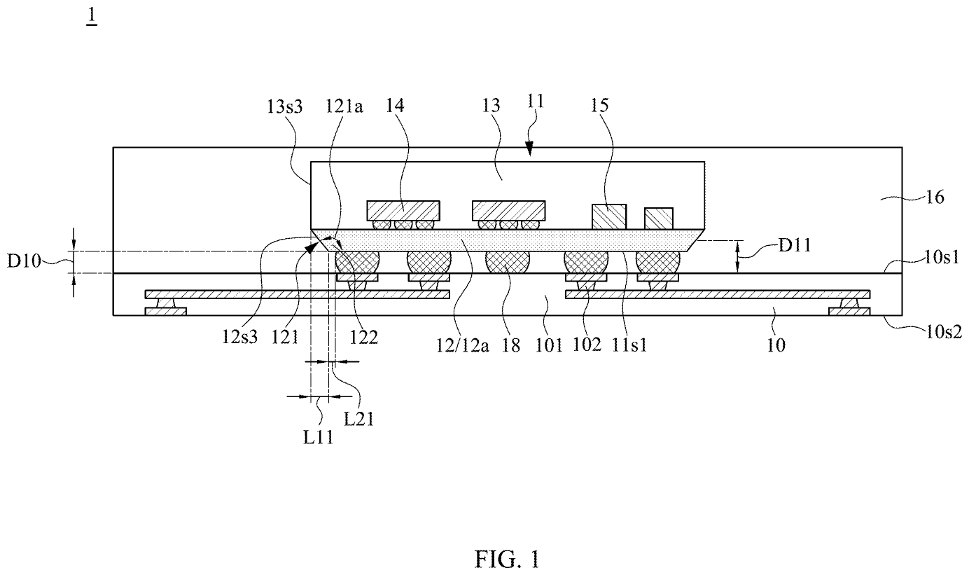

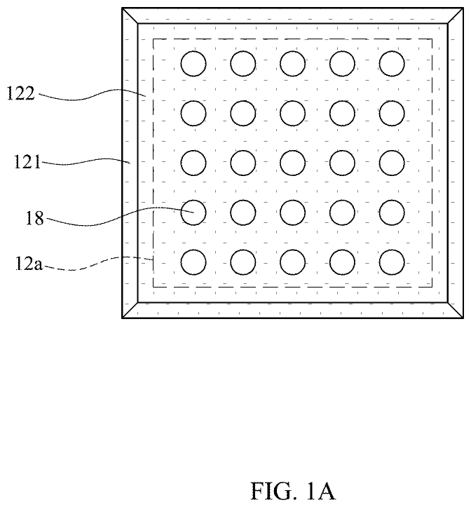

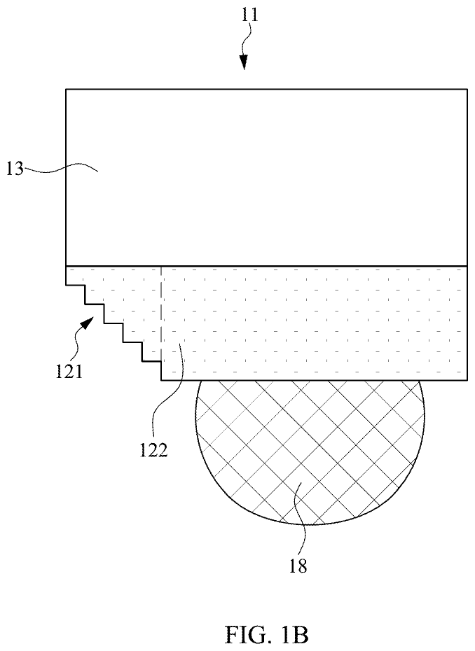

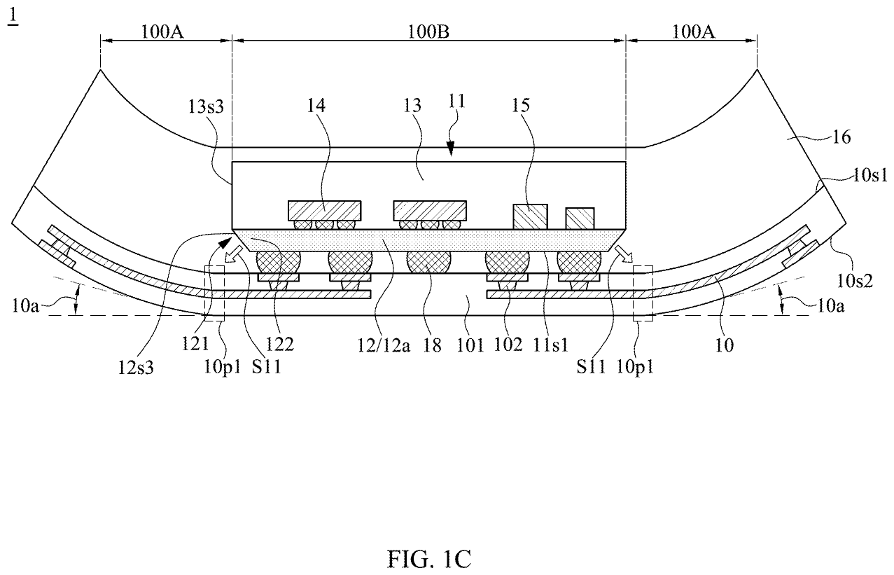

FIG. 1 is a cross-section of an electronic device 1 according to some embodiments of the present disclosure. The electronic device 1 may include a circuit structure 10, a package structure 11, and an encapsulation layer 16. The package structure 11 may be supported by the circuit structure 10. The package structure 11 may be covered or encapsulated by the encapsulation layer 16.

The circuit structure (or a carrier, a substrate) 10 may have a first surface (or upper surface) 10s1 and a second surface (or lower surface) 10s2 opposite to the first surface 10s1. The first surface 10s1 may face the package structure 11 and/or the encapsulation layer 16. The second surface 10s2 may face away from the package structure 11 and/or the encapsulation layer 16. The circuit structure 10 may be or include, for example, one or more of a printed circuit board, such as a paper-based copper foil laminate, a composite copper foil laminate, a polymer-impregnated glass-fiber-based copper foil laminate, and so on. The circuit structure 10 may include a dielectric layer 101 and an interconnection structure 102, such as a redistribution layer (RDL) and/or a grounding element. The interconnection structure 102 may be covered or encapsulated by the dielectric layer 101.

The circuit structure 10 may be a flexible circuit structure. In some arrangements, the circuit structure 10 includes pliable materials. An outline or shape of the circuit structure 10 may be configured to be adjustable or pliable. For example, the outline of the circuit structure 10 is pliable, flexible, bendable, and/or twistable. For example, the circuit structure 10 can be adjusted or bent to have a shape that conforms to any structure (e.g., a straight/flat or a non-straight/non-flat structure). In some arrangements, the circuit structure 10 may include a flexible printed circuit (FPC). In some embodiments, the circuit structure 10 may be made of flexible material, such as polyimide (PI) material, modified polyimide (MPI) material, or liquid crystal polymer (LCP) material.

The encapsulation layer 16 may be disposed over or above the first surface 10s1 of the circuit structure 10. The encapsulation layer 16 may be disposed between the package structure 11 and the circuit structure 10. The encapsulation layer 16 may be a flexible encapsulation layer. The encapsulation layer 16 can include a thermoplastic material. The encapsulation layer 16 can include a molding compound. The encapsulation layer 16 can include resin. The encapsulation layer 16 can include soft or flexible material(s). The encapsulation layer 16 can include thermoplastic polyurethane (TPU), silicone, or the like. The encapsulation layer 16 can include homogeneous material. The encapsulation layer 16 can be devoid of fillers. The encapsulation layer 16 can be devoid of particles.

The package structure 11 may include a system in package (SiP). The package structure 11 may be electrically connected to the circuit structure 10 (e.g., the interconnection structure 102). The package structure 11 may be disposed over or above the first surface 10s1 of the circuit structure 10. The package structure 11 may have a bottom surface 11s1 facing the circuit structure 10. A pliability of the package structure 11 may be smaller than a pliability of the circuit structure 10. The pliability of the package structure 11 may be smaller than a pliability of the encapsulation layer 16.

The electronic device 1 may be examined under a bending test (e.g., a rolling test or twisting test) to obtain its reliability or endurance. The package structure 11 may include a stress-dissipating part at a periphery region of the package structure. The stress-dissipating part is configured to dissipate stress between the package structure 11 and the circuit structure 10. The stress-dissipating part is configured to dissipate stress from the package structure 11 on the circuit structure 10, e.g., a portion of the circuit structure 10 directly under the periphery region of the package structure 11. The stress-dissipating part can prevent the occurrence of cracks or reduce the possibility thereof in the circuit structure 10, e.g., a portion of the circuit structure 10 directly under the periphery region of the package structure 11. The stress-dissipating part may be referred to as an edge, a beveled edge, or a periphery portion of the package structure. A detailed description of the stress-dissipating part will be discussed as below.

The package structure 11 includes a substrate 12, an encapsulation layer 13, an electronic component 14, an electronic component 15, and a plurality of connection elements 18.

The substrate (or a carrier, or a circuit structure) 12 may include a dielectric layer and an interconnection structure surrounded by the dielectric layer. In some embodiments, the substrate 12 may include, for example, a printed circuit board (PCB), such as a paper-based copper foil laminate, a composite copper foil laminate, or a polymer-impregnated glass-fiber-based copper foil laminate. In some embodiments, the substrate 12 may include a semiconductor substrate including silicon, germanium, or other suitable materials. A pliability of the substrate 12 may be smaller than a pliability of the circuit structure 10. In some embodiments, The Young's modulus of the substrate 12 may be greater than the Young's modulus of the circuit structure 10.

The electronic component 14 may be supported by the substrate 12. The electronic component 14 may be disposed over the substrate 12. The electronic component 14 may be electrically connected to the substrate 12 through a plurality of connection elements (e.g., solder bumps). In some embodiments, the electronic component 14 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the electronic component 14 may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). In some embodiments, the processing element may be a CPU chiplet, a MCU chiplet, a GPU chiplet, an ASIC chiplet, or the like. The memory element may be a cache memory.

The electronic component 15 may be supported by the substrate 12. The electronic component 15 may be disposed over the substrate 12. The electronic component 15 may be electrically connected to the substrate 12 through surface mount technology (SMT). The electronic component 15 may be electrically connected to the electronic component 14 through the substrate 12. The electronic component 15 may be or include a surface mount device (SMD). The electronic component 15 may be or include a passive device, e.g., a capacitor, a resistor, an inductor, a diode, or the like. The electronic component 15 may be or include an active device, e.g., a transistor.

The encapsulation layer 13 may cover or encapsulate the electronic components 14 and 15. The encapsulation layer 13 may have a lateral surface 13s3 which is referred to as the lateral surface of the package structure 11. The encapsulation layer 13 may be in contact with the encapsulation layer 16. The encapsulation layer 13 may be covered by the encapsulation layer 16. The encapsulation layer 13 may include an epoxy resin including fillers, a molding compound (e.g., an epoxy molding compound or other molding compound), polyimide, a phenolic compound or material, a material including silicone dispersed therein, or a combination thereof. A pliability of the encapsulation layer 13 may be smaller than a pliability of the encapsulation layer 16. In some embodiments, The Young's modulus of the encapsulation layer 13 may be greater than the Young's modulus of the encapsulation layer 16.

As previously discussed, the package structure 11 may include a stress-dissipating part at its periphery region to dissipate stress between the package structure 11 and the circuit structure 10. The stress-dissipating part is configured to dissipate stress from the package structure 11 on the circuit structure 10. The package structure 11 may include a stress-dissipating part 121 at the periphery region of the package structure 11. The substrate 12 may define the stress-dissipating part 121 may be referred to as an edge or a periphery portion. The substrate 12 may include or define a central region (or a first region) 12a and a second region 122 disposed between the stress-dissipating part 121 and the central region 12a. The second region 122 may extend from the stress-dissipating part 121 and the central region 12a. A first distance D10 between the central region 12a and the circuit structure 10 is shorter than a second distance D11 between the stress-dissipating part 121 and the circuit structure 10. The first distance D10 may be a distance between the bottom surface 11s1 and the upper surface 10s1. The second distance D11 may be a distance between a middle point of the stress-dissipating part 121 and the upper surface 10s1 of the circuit structure 10.

FIG. 1A is a bottom view of a package structure of an electronic device according to some embodiments of the present disclosure. The central region 12a may be connected to the plurality of connection elements 18. The central region 12a may include a plurality of pads (not shown due to being covered by the connection elements 18) configured to connect to the plurality of connection elements 18. In some embodiments, the connection elements 18 may include solder balls, controlled collapse chip connection (C4) bumps, a ball grid array (BGA), or a land grid array (LGA). The central region 12a may be responsible for the electrical connection between the package structure 11 and the circuit structure 10. The stress-dissipating part 121 and the second region 122 may define a non-electrical region of the substrate 12. In some embodiments, the stress-dissipating part 121 and the second region 122 may be made of dielectric material, and no electrical element is included. In some embodiments, the stress-dissipating part 121 and the second region 122 include no conductive pads.

Referring back to FIG. 1, the stress-dissipating part 121 may include a beveled edge in a cross-sectional view. The stress-dissipating part 121 may taper toward the circuit structure 10. The stress-dissipating part 121 may have a surface (or a lateral surface, a slope) 12s3 facing the circuit structure 10. The surface 12s3 may be slanted with respect to the lateral surface 13s3 or the bottom surface 11s1. The surface 12s3 may be non-parallel to the upper surface 10s1 of the circuit structure 10. The surface 12s3 may be non-perpendicular to the lateral surface 13s3 of the package structure 11. A first length L11 of the stress-dissipating part 121 projecting on the circuit structure 10 (or the first surface (or the upper surface) 10s1) may be greater than a second length L21 of the second region 122 projecting on the circuit structure 10 (or the first surface 10s1). The sum of the first length L11 and the second length L21 may be constant, e.g., around 100 mm. An angle (or an interior angle) 121a defined by the stress-dissipating part (or the beveled edge) 121 and the bottom surface 11s1 may be adjusted by the ratio of the first length L11 and the second length L21. For example, when the first length L11 increases and the second length L21 correspondingly decreases (i.e., the ratio thereof increases), the angle 121a will be enlarged.

FIG. 1B is an enlarged view of the periphery region of a package structure (e.g., the package structure 11) in FIG. 1. In microscopic scale, the stress-dissipating part 121 may have a stepped structure tapering toward the circuit structure 10. The stepped structure may be formed by laser etching/cutting. In macroscopic scale, the stress-dissipating part 121 may have a smooth tapering profile. In some embodiments, the stress-dissipating part 121 may be formed by a V-cut and thus have a smooth tapering profile in macroscopic scale and microscopic scale.

FIG. 1C is a cross-section of an electronic device (e.g., the electronic device 1) under a bending test according to some embodiments of the present disclosure. The electronic device may include a region 100A and a region 100B. The region 100A may surround the region 100B. The package structure 11 is located in the region 100B. The package structure 11 is located outside the region 100A. The package structure 11 is a relatively rigid element compared to, e.g., the circuit structure 10 and the encapsulation layer 16. A pliability of the region 100B (which includes the package structure 11) may be greater than a pliability of the region 100A. When the electronic device 1 is bent or twisted, a curvature of the region 100A may be greater than a curvature of the second region 100B. In other words, a radius of curvature of the region 100A may be smaller than a radius of curvature of the region 100B.

The circuit structure 10 may include a portion 10p1 directly under the periphery region of the package structure 11. The portion 10p may be directly below the lateral surface 13s3 of the package structure 11. The portion 10p1 may be located in the boundary of the regions 100A and 100B and endure/withstand a significant degree of deformation when the electronic device 1 is bent. The portion 10p1 bears the relatively strong stress from the package structure 11 when the electronic device 1 is bent. The portion 10p1 may be referred to as a stress concentration portion, which indicates that the portion 10p1 undergoes a higher amount of stress than the other portions of the circuit structure 10. When the electronic device 1 is bent or under a bending test, the portion 10p1 has a relatively high curvature compared to the other portions of the circuit structure 10. The lower surface 10s2 of the circuit structure 10 in the region 100A and the imaginary extension line of the lower surface 10s2 of the circuit structure 10 in the region 100B may define an angle 10a. The dimension of the angle 10a may indicate the curvature of the portion 10p1.

In some cases, a wearable device may include a soft circuit board and an SiP module supported by the soft circuit board. During a bending test, the curvatures are different in a rigid region including the SiP module and the other regions. Thus, the portion of the soft circuit board in the boundary of the regions (i.e., directly under the periphery region of the SiP module) would have a relatively high curvature. The relatively high curvature indicates that the stress in said portion is relatively strong, such that the possibility of the occurrence of cracks in said portion would increase. The cracks may result in an electrical disconnection in the soft circuit board.

In the present disclosure, the package structure 11 includes the stress-dissipating part 121 (or the periphery portion) configured to dissipate stress S11 between the package structure 11 and the circuit structure 10, e.g., the portion 10p1. The stress-dissipating part (or the periphery portion) 121 can prevent the occurrence of cracks or reduce the possibility thereof in the circuit structure 10, e.g., the portion 10p1. The stress-dissipating part 121 has a beveled edge, such that no sharp corners or edges face the portion 10p1. The beveled edge of the stress-dissipating part 121 may dissipate the stress S11 from the package structure 11 to the portion 10p1. When the first length L11 is longer (the second length L21 is correspondingly shorter), the beveled edge of the stress-dissipating part 121 is larger. As such, the stress S11 can be lessened. In a bending test (e.g., a rolling test or twisting test), the electronic device 1 may be placed onto equipment that deliberately changes the curvature of the electronic device 1 to a predetermined level multiple times, to determine its reliability or endurance. With the stress-dissipating part 121, the stress S11 from the package structure 11 to the circuit structure 10 (e.g., the portion 10p1) can be suppressed when the electronic device 1 is under the bending test. The possibility of the occurrence of cracks can be significantly lessened. The reliability or endurance of the electronic device 1 can thus be improved.

Furthermore, the beveled edge of the stress-dissipating part 121 is configured to guide the encapsulation layer 16 into a space between the circuit structure 10 and the package structure 11 during the formation of the encapsulation layer 16. Therefore, the beveled edge of the stress-dissipating part 121 aids in the flow of the encapsulation layer 16, preventing voids from forming between the connection elements 18.

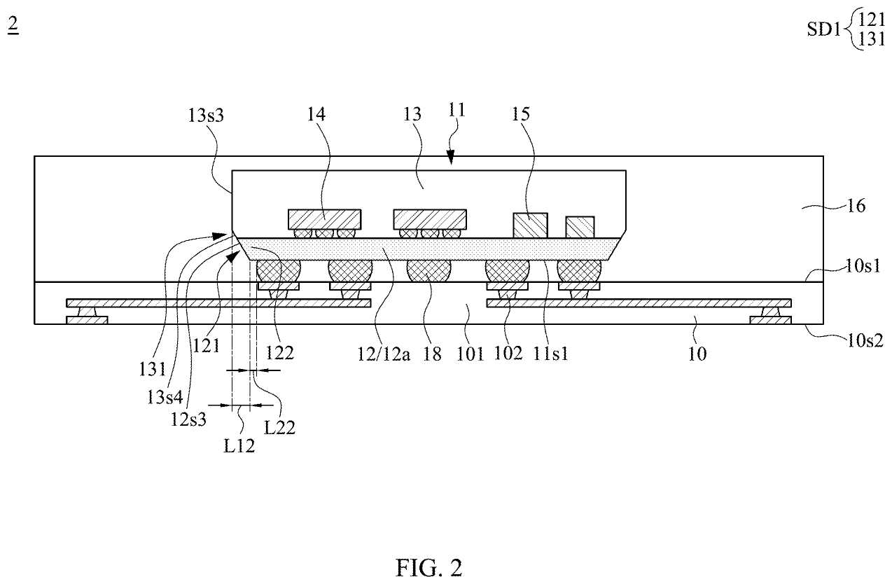

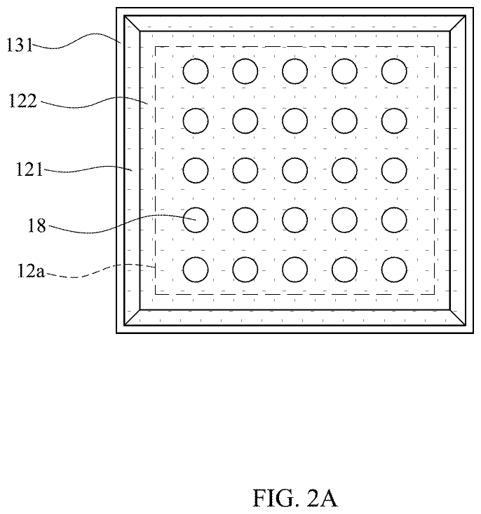

FIG. 2 is a cross-section of an electronic device 2 according to some embodiments of the present disclosure. FIG. 2A is a bottom view of the package structure 11 of the electronic device 2 according to some embodiments of the present disclosure. The electronic device 2 in FIG. 2 is similar to the electronic device 1 in FIG. 1. Therefore, some detailed descriptions may refer to corresponding preceding paragraphs and are not repeated hereinafter for conciseness, with differences therebetween as follows.

The substrate 12 may be disposed between the encapsulation layer 13 and the circuit structure 10. The substrate 12 and the encapsulation layer 13 may collectively define a stress-dissipating part (or a heterogeneous stress-dissipating part) SD1. The substrate 12 may include a section 121 of the stress-dissipating part SD1 and the encapsulation layer 13 may include a section 131 of the stress-dissipating part SD1. The section 131 may be referred to as a stress-dissipating part that is defined by the encapsulation layer 13. The section 121 and the section 131 may be formed in the same process, e.g., a V-cut or laser cut. The section 131 of the encapsulation layer 13 may have a surface (or a lateral surface) 13s4 that is slanted with respect to the lateral surface 13s3. Each of the section 121 and the section 131 may have a beveled edge, and the beveled edge of the section 121 is continuous with the beveled edge of the section 131. The surface 13s4 of the section 131 is continuous with the surface 12s3 of the section 121.

The stress-dissipating part SD1 has a length L12 projecting on the circuit structure 10 (or the first surface 10s1) and greater than the length L11 as shown in FIG. 1. The stress-dissipating part SD1 is configured to dissipate stress from the package structure 11 on the circuit structure 10, e.g., the portion directly under the periphery region of the package structure 11. The stress-dissipating part SD1 can prevent the occurrence of cracks or reduce the possibility thereof in the circuit structure 10. The reliability or endurance of the electronic device 2 can thus be improved.

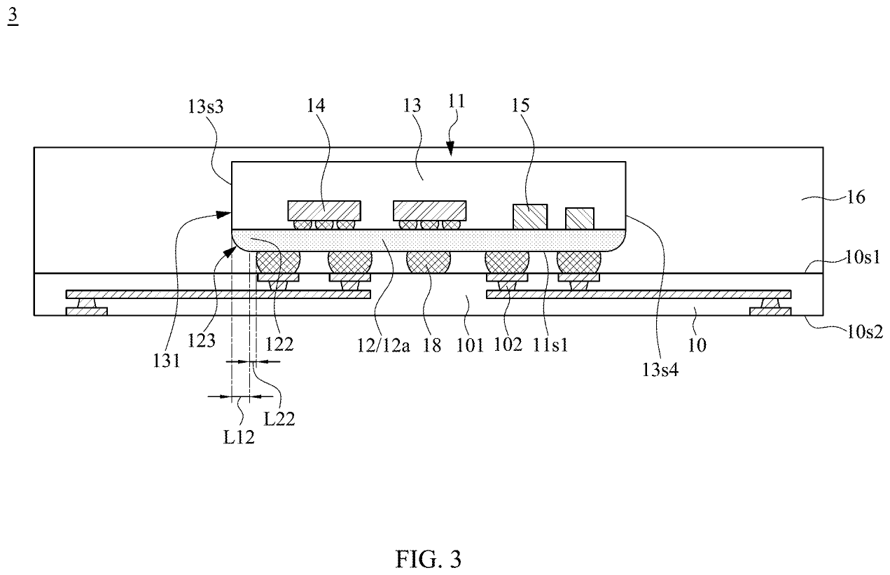

FIG. 3 is a cross-section of an electronic device 3 according to some embodiments of the present disclosure. The electronic device 3 in FIG. 3 is similar to the electronic device 1 in FIG. 1. Therefore, some detailed descriptions may refer to corresponding preceding paragraphs and are not repeated hereinafter for conciseness, with differences therebetween as follows.

The electronic device 3 may include a stress-dissipating part (or a periphery portion, an edge) 123 having a curved edge. Therefore, the stress-dissipating part 123 has no interior angle (e.g., the angle 121a in FIG. 1). The stress-dissipating part 123 with the curved edge is configured to dissipate stress from the package structure 11 on the circuit structure 10, e.g., the portion directly under the periphery region of the package structure 11. The stress-dissipating part 123 can prevent the occurrence of cracks or reduce the possibility thereof in the circuit structure 10. The reliability or endurance of the electronic device 3 can thus be improved.

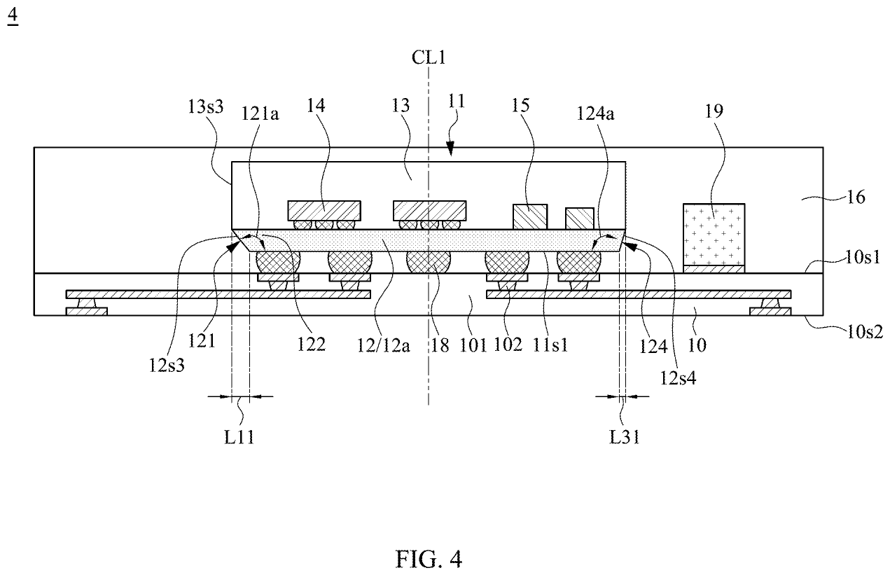

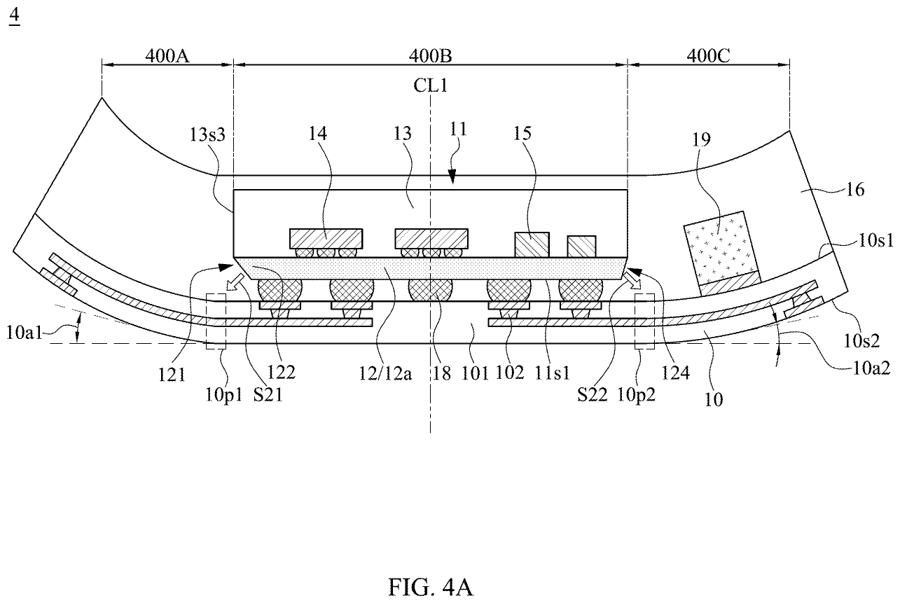

FIG. 4 is a cross-section of an electronic device 4 according to some embodiments of the present disclosure. The electronic device 4 in FIG. 4 is similar to the electronic device 1 in FIG. 1. Therefore, some detailed descriptions may refer to corresponding preceding paragraphs and are not repeated hereinafter for conciseness, with differences therebetween as follows.

The electronic device 4 may further include an electronic component 19 disposed over the circuit structure 10. The electronic component 19 may be supported by the circuit structure 10. The electronic component 19 may be connected to the circuit structure 10 through SMT. The electronic component 19 and the package structure 11 may be disposed side-by-side. The height of the package structure 11 is greater than the electronic component 19 in a direction perpendicular to the first surface 10s1 of the circuit structure 10. The package structure 11 occupies a volume in the electronic device 4 larger than the electronic component 19.

The package structure 11 of the electronic device 4 may further include a stress-dissipating part (or a periphery portion, an edge) 124 at the periphery region of the package structure 11. The stress-dissipating part 124 may be configured to dissipate stress between the package structure 11 and the circuit structure 10. The stress-dissipating part 124 may be configured to dissipate stress from the package structure 11 to the circuit structure 10. The stress-dissipating part 124 may be geometric distinct from the stress-dissipating part 121. The stress-dissipating part 124 may be asymmetrical to the stress-dissipating part 121 with respect to a central line CL1 of the package structure 11. The stress-dissipating part 124 may be opposite to the stress-dissipating part 121. The stress-dissipating part 124 is closer to the electronic component 19 than the stress-dissipating part 121.

The stress-dissipating part 124 may include a beveled edge. The stress-dissipating part 124 may have a surface (or a lateral surface) 12s4. The surface 12s4 is slanted with respect to the lateral surface 13s3 or the bottom surface 11s1. The bottom surface 11s1 and the stress-dissipating part (or the beveled edge) 124 may define an angle (or interior angle) 124a. The angle 121a at the stress-dissipating part 121 is different than the angle 124a at the second stress-dissipating part 124. The first length (or dimension) L11 of the stress-dissipating part 121 may be different from a length (or dimension) L31 of the stress-dissipating part 124 projecting on the circuit structure 10 (or the upper surface 10s1).

FIG. 4A is a cross-section of the electronic device 4 under a bending test according to some embodiments of the present disclosure. The electronic device may include a region 400A, a region 400B, and a region 400C. The region 400B may be between the region 400A and the region 400C. The region 400A may be distant from the region 400C. The package structure 11 is located within the region 400B. The electronic component 19 is located within the region 400C. The package structure 11 is located outside the region 400A and the region 400C. The package structure 11 and the electronic component 19 are relatively rigid elements compared to, e.g., the circuit structure 10 and the encapsulation layer 16. A pliability of the region 400A may be greater than a pliability of the region 400C (which includes the electronic component 19). Since the electronic component 19 occupies less volume than the package structure 11, the pliability of the region 400C (which includes the electronic component 19) is greater than the pliability of the region 400B (which includes the package structure 11).

The package structure 11 may be configured to allow the region 400A and the region 400C bending toward the package structure 11 in different extents. For example, when the electronic device 4 is bent (or under the bending test), a curvature of the region 400A may be greater than a curvature of the region 400C, which may be greater than a curvature of the region 400B. In other words, a radius of curvature of the region 400A may be smaller than a radius of curvature of the region 400C, which may be smaller than a radius of curvature of the region 400B.

The circuit structure 10 may include a portion 10p1 and portion 10p2 directly under the periphery region of the package structure 11. The portion 10p1 may be located in the boundary of the region 400A and 400B and bear the relatively strong stress from the package structure 11 when the electronic device 4 is bent. The portion 10p2 may be located in the boundary of the region 400C and 400B and bear the relatively strong stress from the package structure 11 when the electronic device 4 is bent.

The portions 10p1 and 10p2 may each be referred to as a stress concentration portion, which indicates that the portions 10p1 and 10p2 undergo a higher amount of stress than the surrounding area of the circuit structure 10. When the electronic device 4 is bent or under a bending test, the portion 10p1 may have a relatively high curvature compared to the other portions of the circuit structure 10. The lower surface 10s2 of the circuit structure 10 in the region 400A and the imaginary extension line of the lower surface 10s2 of the circuit structure 10 in the region 400B may define an angle 10a1. The dimension of the angle 10al may indicate the curvature of the portion 10p1. When the electronic device 4 is bent or under a bending test, the portion 10p2 may have a curvature lower than that of the portion 10p1. The lower surface 10s2 of the circuit structure 10 in the region 400C and the imaginary extension line of the lower surface 10s2 of the circuit structure 10 in the region 400B may define an angle 10a2, which is smaller than the angle 10a1.

The stress-dissipating part (or the edge) 121 may be proximate to the region 400A and the stress-dissipating part (or the edge) 124 may be proximate to the region 400C. The stress-dissipating part 121 is configured to dissipate stress S21 (at the region 400A) from the package structure 11 on the circuit structure 10, e.g., the portion 10p1, and the stress-dissipating part 124 is configured to dissipate stress S22 (at the region 400C) from the package structure 11 on the circuit structure 10, e.g., the portion 10p2. The stress-dissipating part 121 and the stress-dissipating part 124 can prevent the occurrence of cracks or reduce the possibility thereof in the circuit structure 10, e.g., the portion 10p1 and the portion 10p2. The stress-dissipating part 121 and the stress-dissipating part 124 each has a beveled edge, such that no sharp corners or edges face the portion 10p1 or the portion 10p2. The beveled edge of the stress-dissipating part 121 may dissipate the stress S21 from the package structure 11 to the portion 10p1. The beveled edge of the stress-dissipating part 124 may dissipate the stress S22 from the package structure 11 to the portion 10p2.

Since the region 400C accommodates the rigid electronic component 19, the region 400C may have a smaller curvature than the region 400A in the bending test. Therefore, the stress S22 applied on the portion 10p2 is smaller than the stress S21 applied on the portion 10p1. As such, the beveled edge of the stress-dissipating part 124 can be designed to be steeper than the beveled edge of the stress-dissipating part 121, since the stress-dissipating part 124 with the shorter length L31 is sufficient to suppress the relatively small stress S22. The stress-induced issues, such as cracks, of the uneven/non-uniform assembly of the electronic device 4 can be addressed by the design of the slope or the length of the stress-dissipating parts (e.g., asymmetrical stress-dissipating parts 121 and 124). The reliability or endurance of the electronic device 4 can thus be improved.

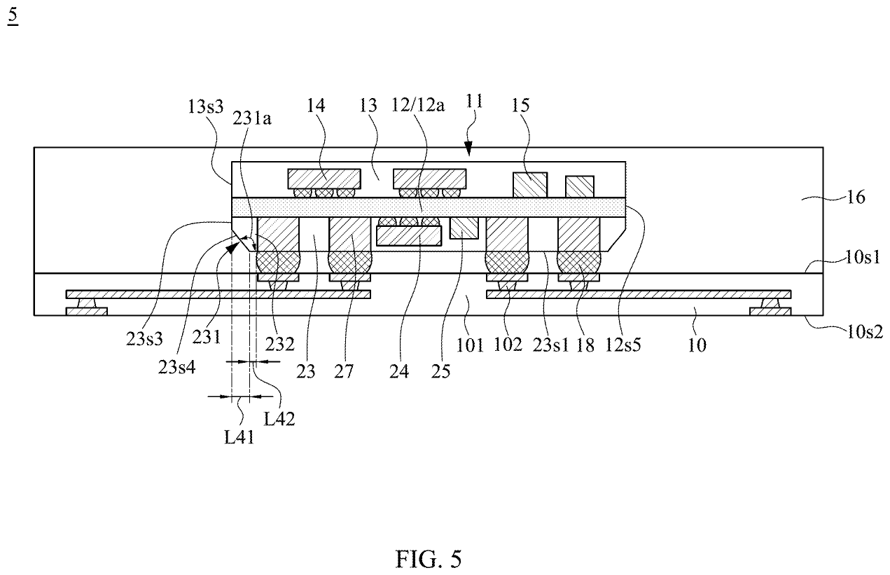

FIG. 5 is a cross-section of an electronic device 5 according to some embodiments of the present disclosure. The electronic device 5 in FIG. 5 is similar to the electronic device 1 in FIG. 1. Therefore, some detailed descriptions may refer to corresponding preceding paragraphs and are not repeated hereinafter for conciseness, with differences therebetween as follows.

The package structure 11 may further include an encapsulation layer 23, an electronic component 24, an electronic component 25, and a conductive element 27. The package structure 11 may be or include a dual-side SiP module.

The electronic component 24 may be supported by the substrate 12. The electronic component 24 may be disposed under the substrate 12. The electronic component 24 may be electrically connected to the substrate 12 through a plurality of connection elements (e.g., solder bumps). The electronic component 24 may be similar to the electronic component 14. In some embodiments, the electronic component 24 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit.

The electronic component 25 may be supported by the substrate 12. The electronic component 25 may be disposed under the substrate 12. The electronic component 25 may be electrically connected to the substrate 12 through SMT. The electronic component 25 may be electrically connected to the electronic component 24 through the substrate 12. The electronic component 25 may be or include an SMD. The electronic component 25 may be or include a passive device, e.g., a capacitor, a resistor, an inductor, a diode, or the like. The electronic component 25 may be or include an active device, e.g., a transistor.

Two or more of the electronic components 14, 15, 24, and 25 may be electrically connected through the substrate 12.

The conductive element 27 may be supported by the substrate 12. The conductive element 27 may be disposed under the substrate 12. The conductive element 27 may extend or penetrate through the encapsulation layer 23. The package structure 11 may be electrically connected to the circuit structure 10 through the conductive element 27. The conductive element 27 may be or include a conductive pillar, a conductive via, etc. The conductive element 27 may be made of metal, such as copper, gold, silver, aluminum, titanium, tantalum, or the like.

The encapsulation layer 23 may be disposed under the substrate 12. The substrate 12 may be disposed over the encapsulation layer 23. The encapsulation layer 23 may be disposed between the substrate 12 and the circuit structure 10. The encapsulation layer 23 may have a bottom surface 23s1 facing the circuit structure 10. The encapsulation layer 23 is opposite to the encapsulation layer 13. The encapsulation layer 23 may cover or encapsulate the electronic components 24 and 25 and the conductive element 27. The encapsulation layer 23 may have a lateral surface 23s3. The encapsulation layer 23 may be in contact with the encapsulation layer 16. The encapsulation layer 23 may be covered or encapsulated by the encapsulation layer 16. The encapsulation layer 23 may include an epoxy resin including fillers, a molding compound (e.g., an epoxy molding compound or other molding compound), polyimide, a phenolic compound or material, a material including silicone dispersed therein, or a combination thereof. A pliability of the encapsulation layer 23 may be smaller than a pliability of the encapsulation layer 16. In some embodiments, the Young's modulus of the encapsulation layer 23 may be greater than the Young's modulus of the encapsulation layer 16.

The substrate 12 may have a lateral surface 12s5 substantially aligned with the lateral surface 13s3 of the encapsulation layer 13 and the lateral surface 23s3 of the encapsulation layer 23. The encapsulation layer 23 may include or define a stress-dissipating part (or a periphery portion, an edge) 231 and a second region 232. The stress-dissipating part 231 and the second region 232 may define a non-electrical region of the substrate 12. In some embodiments, the stress-dissipating part 231 and the second region 232 may be made of a molding compound, and no electrical element is included. In some embodiments, the stress-dissipating part 231 and the second region 232 include no conductive elements.

The stress-dissipating part 231 may include a beveled edge in a cross-sectional view. The stress-dissipating part 231 may taper toward the circuit structure 10. The stress-dissipating part 231 may have a surface (or a lateral surface) 23s4 facing the circuit structure 10. The lateral surface 23s4 is slanted with respect to the lateral surface 23s3, the lateral surface 12s5, or the bottom surface 23s1. A first length L41 of the stress-dissipating part 231 projecting on the circuit structure 10 (or the first surface 10s1) may be different than a second length L42 of the second region 232 projecting on the circuit structure 10 (or the first surface 10s1). The sum of the first length L41 and the second length L42 may be constant, e.g., around 100 mm. An angle (or an interior angle) 231a defined by the stress-dissipating part (or the beveled edge) 231 and the bottom surface 23s1 may be adjusted by the ratio of the first length L41 and the second length L42. For example, when the first length L41 increases and the second length L42 correspondingly decreases (i.e., the ratio thereof increases), the angle 231a will be enlarged.

In some embodiments, the stress-dissipating part 231 may have a stepped structure in microscopic scale similar to that as shown in FIG. 1B. In macroscopic scale, the stress-dissipating part 231 may have a smooth tapering profile. In some embodiments, the stress-dissipating part 231 may be formed by a V-cut and thus have a smooth tapering profile in macroscopic scale and microscopic scale.

The stress-dissipating part 231 is at a periphery region of the package structure 11 and configured to dissipate stress between the package structure 11 and the circuit structure 10, e.g., a portion of the circuit structure 10 directly under the periphery region of the package structure 11. The stress-dissipating part 231 can prevent the occurrence of cracks or reduce the possibility thereof in the circuit structure 10, e.g., a portion of the circuit structure 10 directly under the periphery region of the package structure 11. The stress-dissipating part 231 has a beveled edge, such that no sharp corners or edges face said portion. The beveled edge of the stress-dissipating part 231 may dissipate the stress from the package structure 11 to said portion. In a bending test (e.g., a rolling test or twisting test), the electronic device 5 may be placed onto equipment that deliberately changes the curvature of the electronic device 5 to a predetermined level multiple times, to obtain its reliability or endurance. With the stress-dissipating part 231, the stress from the package structure 11 to the circuit structure 10 can be suppressed when the electronic device 5 is under the bending test. The possibility of the occurrence of cracks can be significantly lessened. The reliability or endurance of the electronic device 5 can thus be improved.

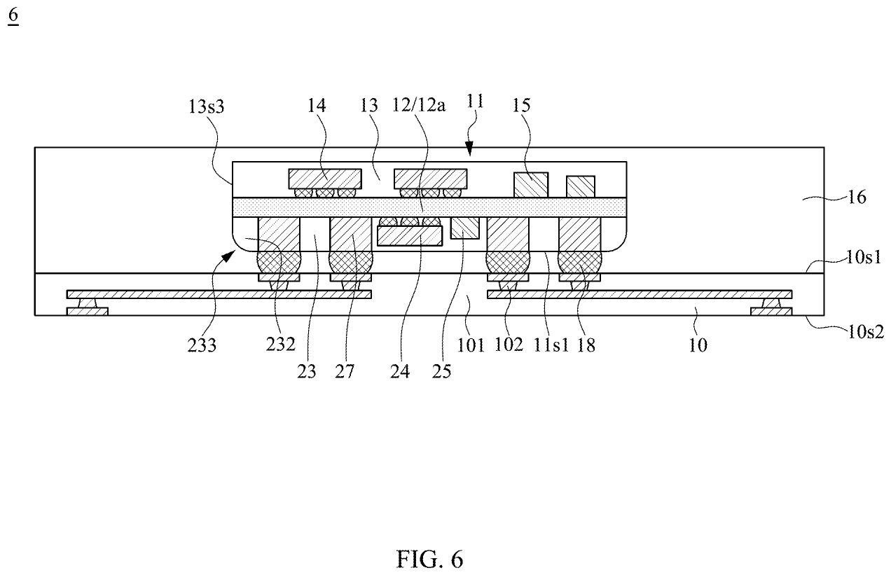

FIG. 6 is a cross-section of an electronic device according to some embodiments of the present disclosure. The electronic device 6 in FIG. 6 is similar to the electronic device 5 in FIG. 5. Therefore, some detailed descriptions may refer to corresponding preceding paragraphs and are not repeated hereinafter for conciseness, with differences therebetween as follows.

The electronic device 6 may include a stress-dissipating part (or a periphery portion, an edge) 233 having a curved edge. Therefore, the stress-dissipating part 233 has no interior angle (e.g., the angle 231a in FIG. 5). The stress-dissipating part 233 with the curved edge is configured to dissipate stress between the package structure 11 and the circuit structure 10, e.g., the portion directly under the periphery region of the package structure 11. The stress-dissipating part 233 can prevent the occurrence of cracks or reduce the possibility thereof in the circuit structure 10. The reliability or endurance of the electronic device 6 can thus be improved.

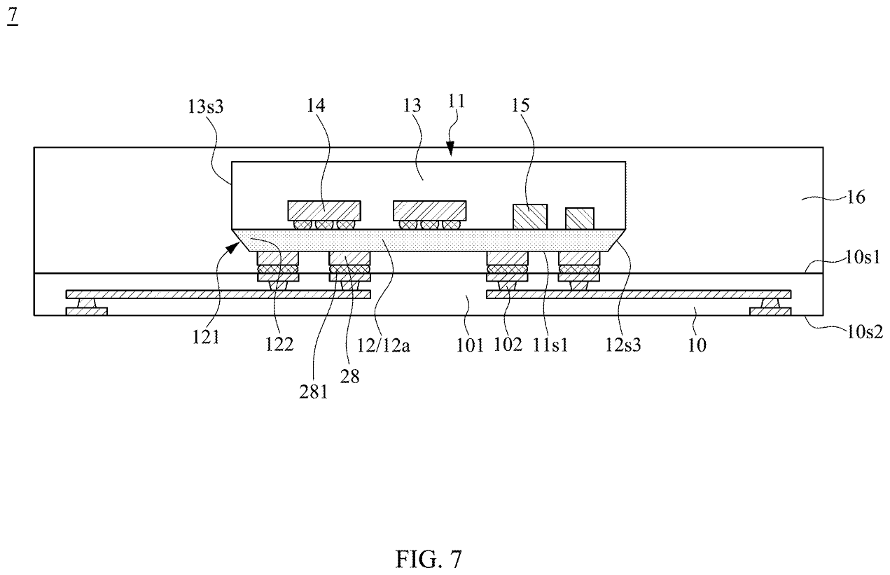

FIG. 7 is a cross-section of an electronic device 7 according to some embodiments of the present disclosure. The electronic device 7 in FIG. 7 is similar to the electronic device 1 in FIG. 1. Therefore, some detailed descriptions may refer to corresponding preceding paragraphs and are not repeated hereinafter for conciseness, with differences therebetween as follows.

The package structure 11 may include a plurality of conductive pillars 28 between the substrate 12 and the circuit structure 10. The conductive pillars 28 are connected to the circuit structure 10 through a plurality of solder bumps 281. The conductive pillars 28 may be made of metal, such as copper, gold, silver, aluminum, titanium, tantalum, or the like.

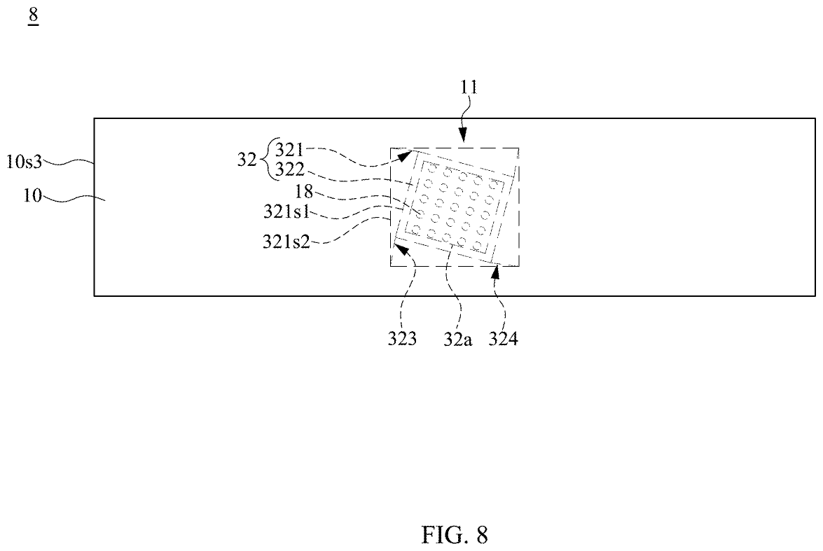

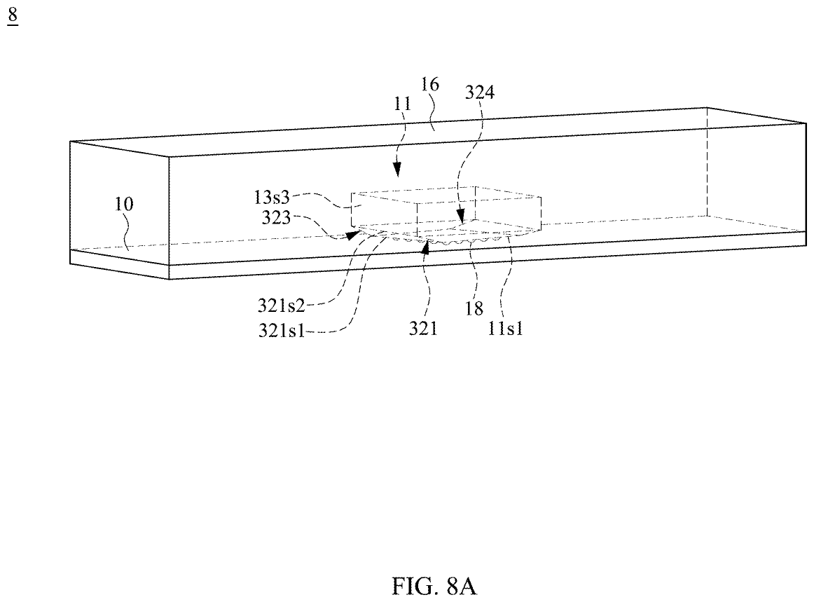

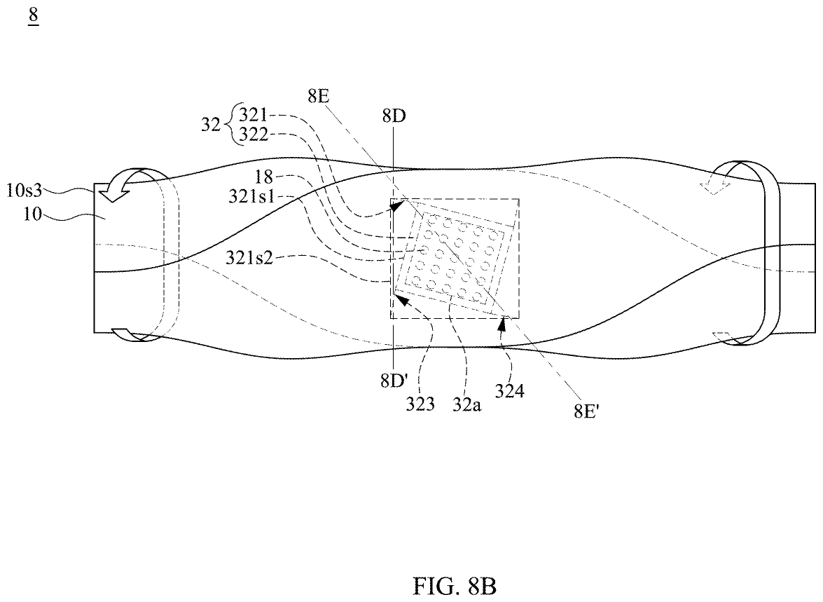

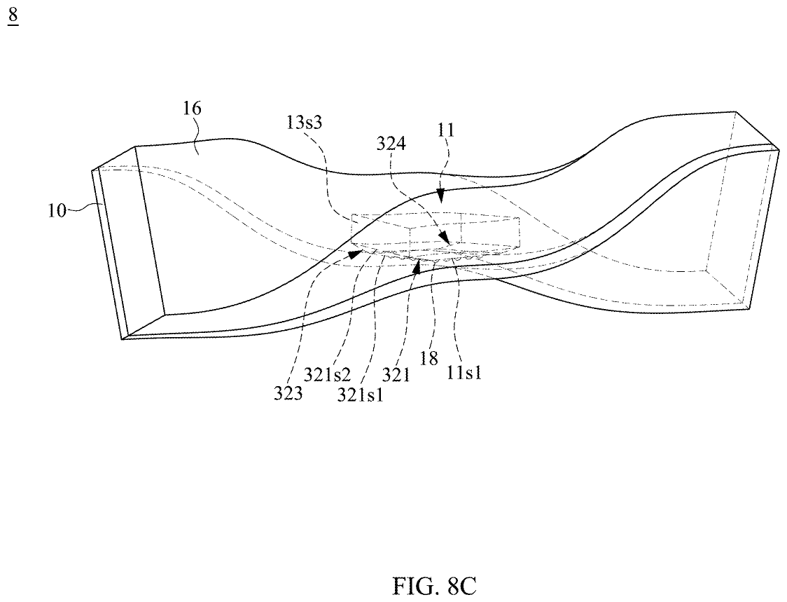

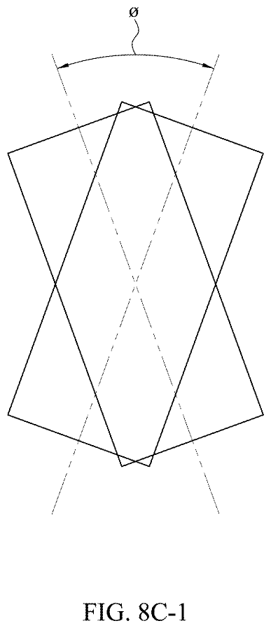

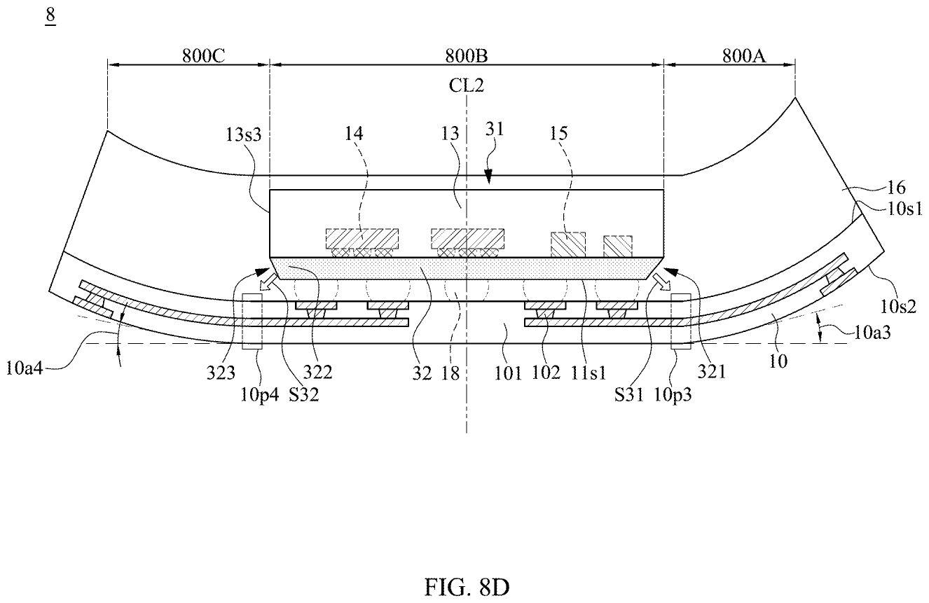

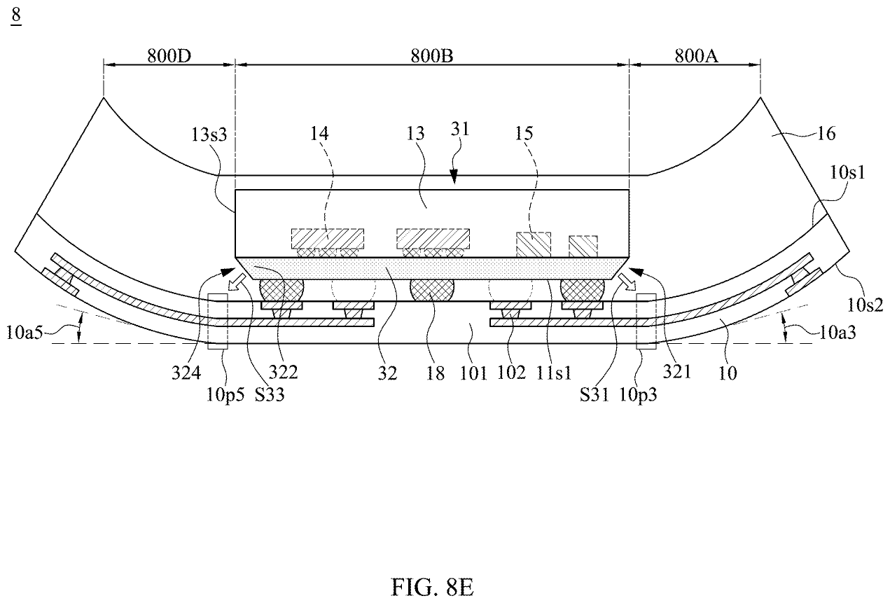

FIG. 8 is a bottom view of an electronic device 8 according to some embodiments of the present disclosure. The electronic device 8 in FIG. 8 is similar to the electronic device 1 in FIG. 1 and FIG. 1A. Therefore, some detailed descriptions may refer to corresponding preceding paragraphs and are not repeated hereinafter for conciseness, with differences therebetween as follows.

The package structure 11 of the electronic device 8 may include a substrate 32 disposed over the circuit structure 10. The substrate 32 may be similar to the substrate 12 in terms of material.

The substrate 32 may be electrically connected to the circuit structure 10 through the connection elements 18. The substrate 32 may include a stress-dissipating part (or a periphery portion, an edge) 321 at its periphery region to dissipate stress between the package structure 11 and the circuit structure 10. The stress-dissipating part 321 may be configured to dissipate stress from the package structure 11 to the circuit structure 10. The substrate 32 may include a central region 32a and a second region 322 disposed between the stress-dissipating part 321 and the central region 32a. The central region 32a may include a plurality of pads (not shown due to being covered by the connection elements 18) configured to connect to the plurality of connection elements 18. The central region 32a may be responsible for the electrical connection between the package structure 11 and the circuit structure 10. The stress-dissipating part 321 and the second region 322 may define a non-electrical region of the substrate 32. In some embodiments, the stress-dissipating part 321 and the second region 322 may be made of dielectric material, and no electrical element is included. In some embodiments, the stress-dissipating part 321 and the second region 322 include no conductive pads.

The substrate 32 may further include a stress-dissipating part (or a periphery portion, an edge) 323 and a stress-dissipating part (or a periphery portion, an edge) 324 at its periphery region to dissipate stress between the package structure 11 and the circuit structure 10. The stress-dissipating part 323 and stress-dissipating part 324 may be configured to dissipate stress from the package structure 11 to the circuit structure 10. The stress-dissipating part 323 may be opposite to the stress-dissipating part 321 along one side of the substrate 32. The stress-dissipating part 324 may be opposite to the stress-dissipating part 321 along the diagonal direction of the substrate 32.

FIG. 8A is a perspective view of the electronic device 8 according to some embodiments of the present disclosure. The stress-dissipating part 321 may include a beveled edge. The stress-dissipating parts 321, 323, and 324 may each taper toward the circuit structure 10. The stress-dissipating parts 321, 323, and 324 may each have a lateral surface facing the circuit structure 10. The lateral surfaces thereof are slanted with respect to the lateral surface 13s3 of the encapsulation layer 13.

In some embodiments, the stress-dissipating parts 321, 323, and 324 may have a stepped structure similar to that as shown in FIG. 1B. In macroscopic scale, the stress-dissipating parts 321, 323, and 324 may have a smooth tapering profile. In some embodiments, the stress-dissipating parts 321, 323, and 324 may be formed by a V-cut and thus have a smooth tapering profile in macroscopic scale and microscopic scale.

Referring back to FIG. 8, the first stress-dissipating part 321 has a first edge 321s1 non-parallel with a lateral edge 10s3 of the circuit structure 10 and a second edge 321s2 non-parallel with the first edge 321s1. The first edge 321s1 may be spaced apart from the second edge in the bottom view of FIG. 8. The lateral edge 10s3 of the circuit structure 10 may be substantially parallel with the second edge 321s2. The substrate 32 may have an asymmetrical shape. As shown in FIG. 8A, the first edge 321s1 is connected to the bottom surface 11s1 of the package structure 11. The second side 321s2 is connected to the lateral surface 13s3 of the encapsulation layer 13.

FIG. 8B is a bottom view of an electronic device (e.g., the electronic device 8) under a twisting test according to some embodiments of the present disclosure. FIG. 8C is a perspective view of an electronic device (e.g., the electronic device 8) under a twisting test according to some embodiments of the present disclosure. FIG. 8C-1 is a side view of an electronic device (e.g., the electronic device 8) under a twisting test according to some embodiments of the present disclosure.

The electronic device 8 may have a small curvature at a first region which includes the package structure 11 and a large curvature at the other regions since the package structure 11 is a relatively rigid element compared to the circuit structure 10 and the encapsulation layer 16. As shown in FIG. 8C, the electronic device 8 can have a twisting angle (denoted as “Φ” in FIG. 8C-1) in a range from about 30° to about 60°, from about 40° to about 50°, or about 45°. Under this twisting angle Φ, the region of the electronic device 8 proximate to the stress-dissipating part 321 and the stress-dissipating part 324 may have a larger curvature than the region of the electronic device 8 proximate to the stress-dissipating part 323. Therefore, the stress-dissipating parts 321, 323, and 324 can be designed to be asymmetrical to the central line of the package structure 11 to improve the twisting reliability or endurance.

FIG. 8D is a cross-section of an electronic device along the line 8D-8D′ in FIG. 8B according to some embodiments of the present disclosure. FIG. 8D depicts the deformation of a region 800A of the electronic device 8 proximate to the stress-dissipating part 321 and a region 800C of the electronic device 8 proximate to the stress-dissipating part 323. The electronic device 8 may include a region 800B disposed between the region 800A and the region 800C.

The package structure 11 may be configured to allow the region 800A and the region 800C bending toward the package structure 11 in different extents. For example, when the electronic device 8 is twisted (or under the twisting test), a curvature of the region 800A may be greater than a curvature of the region 800C, which may be greater than a curvature of the region 800B. In other words, a radius of curvature of the region 800A may be smaller than a radius of curvature of the region 800C, which may be smaller than a radius of curvature of the region 800B.

The circuit structure 10 may include a portion 10p3 and a portion 10p4 directly under the periphery region of the package structure 11. The portion 10p3 and the portion 10p4 may be directly under the lateral surface 13s3. The portion 10p3 may be located in the boundary of the region 800A and 800B and bear the relatively strong stress from the package structure 11 when the electronic device 8 is twisted. The portion 10p4 may be located in the boundary of the region 800C and 800B and bear the relatively small stress from the package structure 11 when the electronic device 8 is twisted.

Owing to the twisting angle Φ, the portion 10p4 does not experience as much twisting as the portion 10p3. The portion 10p3 may be referred to as a stress concentration portion, which indicates that the portion 10p3 undergoes a higher amount of stress S31 than the other portions of the circuit structure 10. The portion 10p4 may undergo stress S32 which is less than stress S31. When the electronic device 8 is twisted or under a twisting test, the portion 10p3 may have a relatively high curvature compared to the other portions of the circuit structure 10. When the electronic device 8 is twisted or under a twisting test, the portion 10p4 may have a curvature lower than that of the portion 10p3. The lower surface 10s2 of the circuit structure 10 in the region 800A and the imaginary extension line of the lower surface 10s2 of the circuit structure 10 in the region 800B may define an angle 10a3. The dimension of the angle 10a3 may indicate the curvature of the portion 10p3. The lower surface 10s2 of the circuit structure 10 in the region 800C and the imaginary extension line of the lower surface 10s2 of the circuit structure 10 in the region 800B may define an angle 10a4, which is smaller than the angle 10a3.

During the formation of the package structure 11, the substrate 32 may be etched via a V-cut or laser cut to define the stress-dissipating parts 321, 323, and 324. The stress-dissipating part 321 may be asymmetrical to the stress-dissipating part 323 with respect to a central line CL2 of the package structure 11. The first edge 321s1 and the second edge 321s2 of the stress-dissipating part 321 are non-parallel. The asymmetrical stress-dissipating parts 321 and 323 can improve the twisting reliability or endurance. The stress-dissipating part 321 is configured to dissipate stress S31 from the package structure 11 on the circuit structure 10, e.g., the portion 10p3, and the stress-dissipating part 323 is configured to dissipate the relatively small stress S32 from the package structure 11 on the circuit structure 10, e.g., the portion 10p4. The stress-dissipating part 321 and the stress-dissipating part 323 can prevent the occurrence of cracks or reduce the possibility thereof in the circuit structure 10, e.g., the portion 10p3 and the portion 10p4. The reliability or endurance of the electronic device 8 can thus be improved.

The stress-dissipating part 321 and the stress-dissipating part 323 each has a beveled edge, such that no sharp corners or edges face the portion 10p3 or the portion 10p4. The beveled edge of the stress-dissipating part 321 may dissipate the stress S31 from the package structure 11 to the portion 10p3. The beveled edge of the stress-dissipating part 323 may dissipate the stress S32 from the package structure 11 to the portion 10p4.

FIG. 8E is a cross-section of an electronic device along the line 8E-8E′ in FIG. 8B according to some embodiments of the present disclosure. FIG. 8E depicts the deformation of a region 800A proximate to the stress-dissipating part 321 and a region 800D proximate to the stress-dissipating part 324. The region 800B may be disposed between the region 800A and the region 800D.

When the electronic device 8 is twisted (or under the twisting test), a curvature of the region 800A may be substantially the same as or similar to a curvature of the region 800D, which may be greater than a curvature of the region 800B. In other words, a radius of curvature of the region 800A may be substantially the same as or similar to a radius of curvature of the region 800D, which may be smaller than a radius of curvature of the region 800B.

The circuit structure 10 may include a portion 10p5 directly under the periphery region of the package structure 11. The portion 10p5 may be directly under the lateral surface 13s3. The portion 10p5 may be located in the boundary of the region 800D and 800B and bear the relatively strong stress from the package structure 11 when the electronic device 8 is twisted. The portion 10p5 may be referred to as a stress concentration portion, which indicates that the portion 10p5 undergoes a higher amount of stress S33 than the other portions of the circuit structure 10. When the electronic device 8 is twisted or under a twisting test, the portion 10p5 may have a relatively high curvature compared to the other portions of the circuit structure 10. The lower surface 10s2 of the circuit structure 10 in the region 800D and the imaginary extension line of the lower surface 10s2 of the circuit structure 10 in the region 800B may define an angle 10a5. The dimension of the angle 10a5 may indicate the curvature of the portion 10p5. The angle 10a5 may be substantially the same as or similar to the angle 10a3.

The stress-dissipating part 324 is configured to dissipate stress S33 from the package structure 11 on the circuit structure 10, e.g., the portion 10p5. The stress-dissipating part 324 can prevent the occurrence of cracks or reduce the possibility thereof in the circuit structure 10, e.g., the portion 10p5. The stress-dissipating part 324 has a beveled edge, such that no sharp corners or edges face the portion 10p5. The beveled edge of the stress-dissipating part 324 may dissipate the stress S33 from the package structure 11 to the portion 10p5. The reliability or endurance of the electronic device 8 can thus be improved.

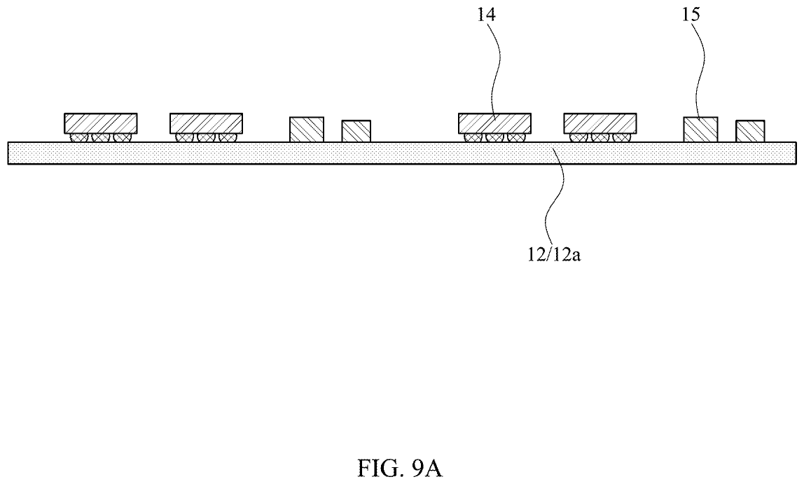

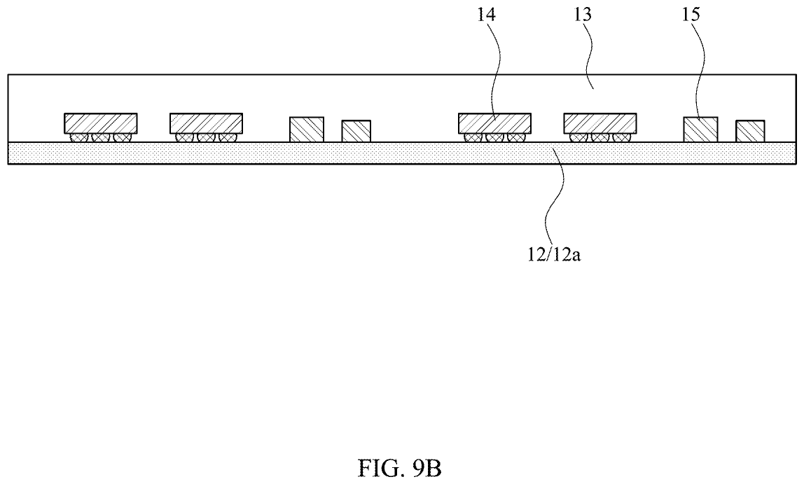

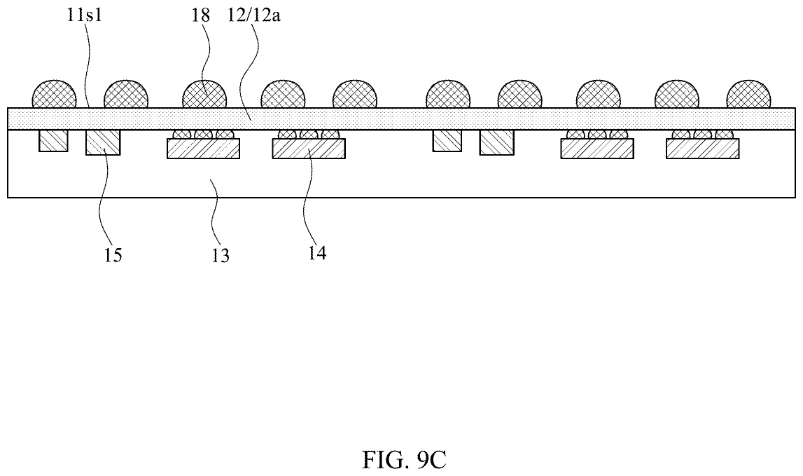

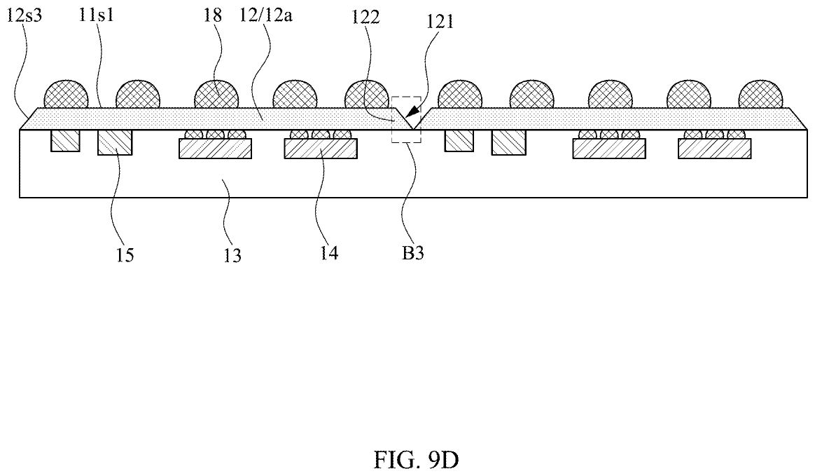

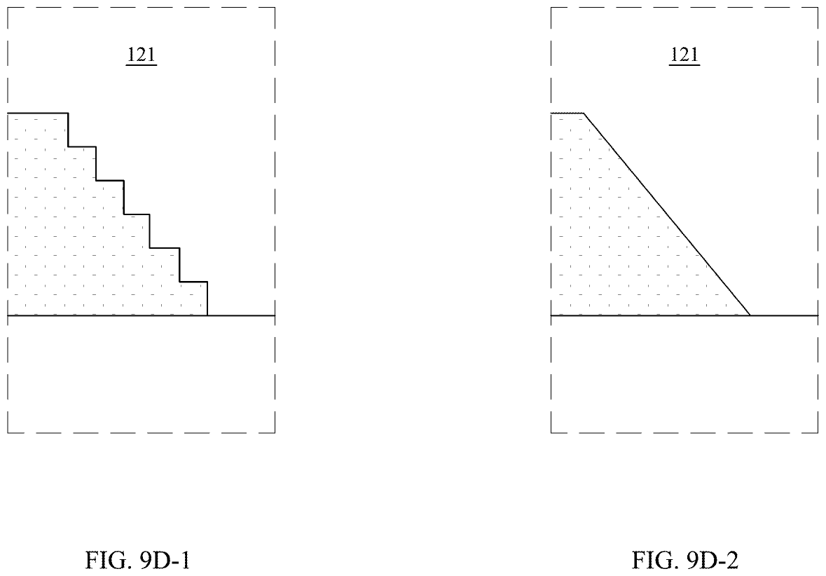

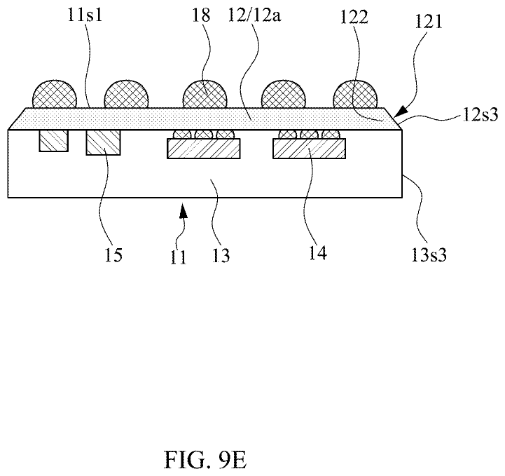

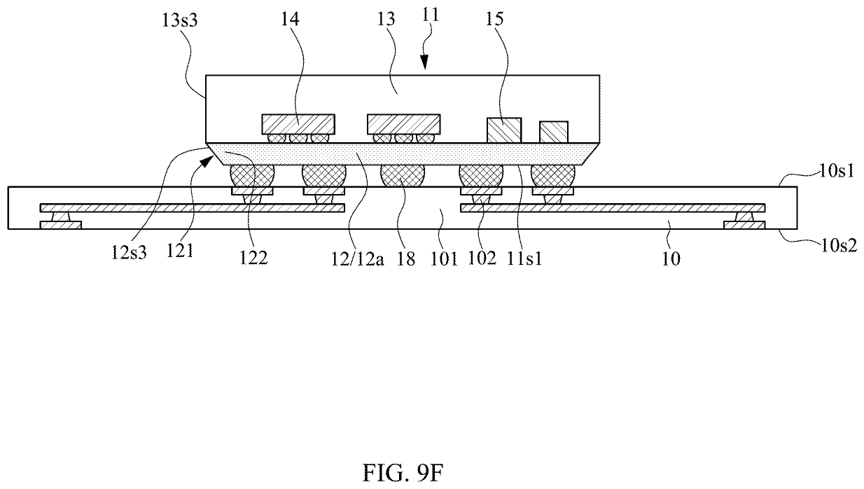

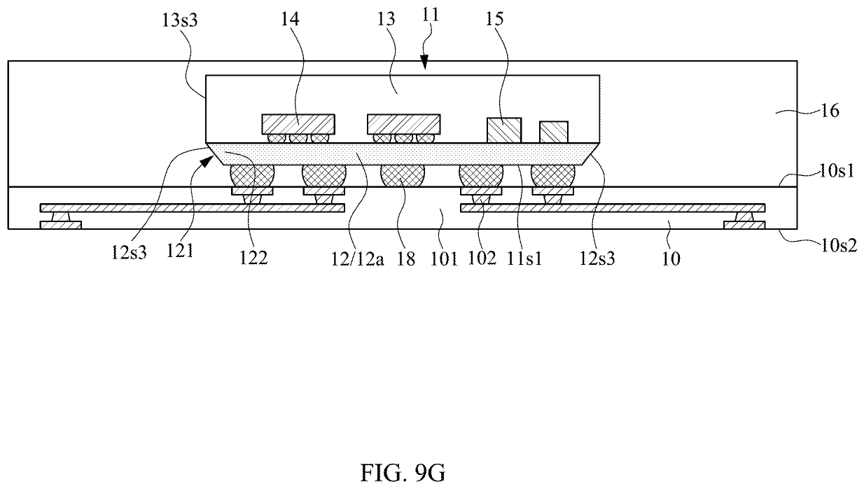

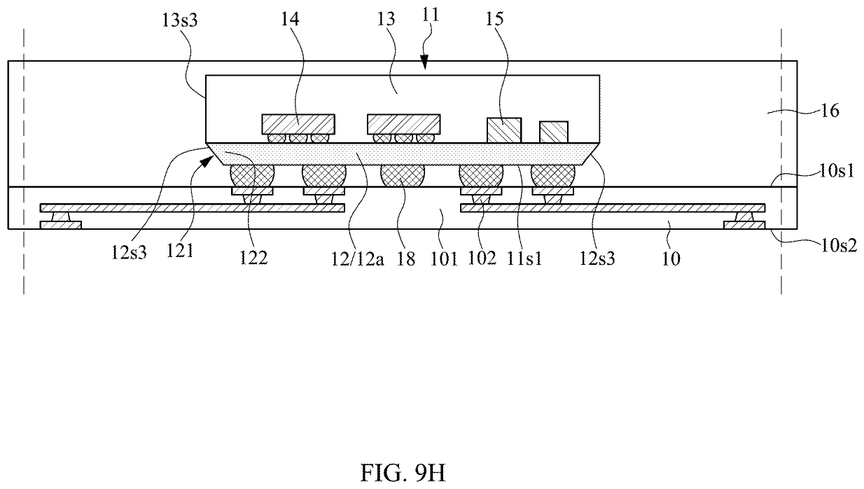

FIGS. 9A, 9B, 9C, 9D, 9E, 9F, 9G, and 9H illustrate one or more stages of an example of a method for manufacturing an electronic device according to some embodiments of the present disclosure.

As shown in FIG. 9A, a substrate 12 may be provided. An electronic component 14 may be attached to the substrate 12 through a plurality of connection elements, e.g., solder bumps. An electronic component 15 may be attached to the substrate 12 through SMT. The substrate 12 may include a central region 12a responsible for the electrical connection with the electronic component 14 and the electronic component 15.

As shown in FIG. 9B, an encapsulation layer 13 may be formed over the substrate 12. The encapsulation layer 13 may cover or encapsulate the electronic component 14 and the electronic component 15.

As shown in FIG. 9C, a plurality of connection elements 18 are mounted to the substrate 12. The connection elements 18 may include solder balls, controlled collapse chip connection (C4) bumps, a ball grid array (BGA), or a land grid array (LGA). The connection elements 18 may be electrically connected to the central region 12a of the substrate 12.

As shown in FIG. 9D, the substrate 12 may be etched via a V-cut or laser cut to form a stress-dissipating part 121. The stress-dissipating part 121 is outside the central region 12a, such that the electrical connection of the substrate 12 is not influenced by the stress-dissipating part 121. The stress-dissipating part 121 may include a beveled edge tapering toward the connection elements 18.

FIG. 9D-1 is an enlarged view of a box B3 in FIG. 9D. FIG. 9D-1 illustrates that the stress-dissipating part 121 has a stepped structure in microscopic scale. The stepped structure is formed by the laser cut (or laser etching). In macroscopic scale, the stress-dissipating part 121 may have a smooth tapering profile.

FIG. 9D-2 is another enlarged view of a box B3 in FIG. 9D. FIG. 9D-2 illustrates that the stress-dissipating part 121 has a smooth tapering profile in microscopic scale and macroscopic scale. The smooth tapering profile as shown in FIG. 9D-2 may be formed by the V-cut.

As shown in FIG. 9E, the substrate 12 may be singulated to form a package structure 11. The package structure 11 may be referred to as an SiP module. The encapsulation layer 13 may be etched to form a lateral surface 13s3. The stress-dissipating part 121 may have a surface 12s3 connected to the lateral surface 13s3. The surface 12s3 is slanted with respect to the lateral surface 13s3.

As shown in FIG. 9E, the package structure 11 may be mounted to a circuit structure 10 through the connection elements 18. The circuit structure 10 may have a first surface (or upper surface) 10s1 and a second surface (or lower surface) 10s2 opposite to the first surface 10s1. The first surface 10s1 may face the package structure 11. The second surface 10s2 may face away from the package structure 11. The circuit structure 10 may include a dielectric layer 101 and an interconnection structure 102, such as a redistribution layer (RDL) and/or a grounding element. The interconnection structure 102 may be covered or encapsulated by the dielectric layer 101.

The circuit structure 10 may be a flexible circuit structure. In some arrangements, the circuit structure 10 includes pliable materials. An outline or shape of the circuit structure 10 may be configured to be adjustable or pliable. For example, the outline of the circuit structure 10 is pliable, flexible, bendable, and/or twistable. For example, the circuit structure 10 can be adjusted or bent to have a shape that conforms to any structure (e.g., a straight/flat or a non-straight/non-flat structure) of the electrical device. In some arrangements, the circuit structure 10 may include a flexible printed circuit (FPC). In some embodiments, the circuit structure 10 may be made of flexible material, such as polyimide (PI) material, modified polyimide (MPI) material, or liquid crystal polymer (LCP) material.

As shown in FIG. 9G, an encapsulation layer 16 may be formed over the circuit structure 10. The encapsulation layer 16 may cover or encapsulate the package structure and the connection elements 18. The beveled edge of the stress-dissipating part 121 can guide the encapsulation layer 16 into a space between the circuit structure 10 and the package structure 11 during the formation of the encapsulation layer 16. Therefore, the beveled edge of the stress-dissipating part 121 aids in the flow of the encapsulation layer 16, preventing voids from forming between the connection elements 18.

The encapsulation layer 16 may be a flexible encapsulation layer. The encapsulation layer 16 can include a thermoplastic material. The encapsulation layer 16 can include a molding compound. The encapsulation layer 16 can include resin. The encapsulation layer 16 can include soft or flexible material(s). The encapsulation layer 16 can include thermoplastic polyurethane (TPU), silicone, or the like. The encapsulation layer 16 can include homogeneous material. The encapsulation layer 16 can be devoid of fillers. The encapsulation layer 16 can be devoid of particles.

As shown in FIG. 9H, the circuit structure 10 and the encapsulation layer 16 may be singulated to form an electronic device (e.g., the electronic device 1 as shown in FIG. 1).

After the manufacture of the electronic device 1, it may be examined in a bending test (e.g., a rolling test or twisting test). The bending test may include placing the electronic device 1 onto equipment that deliberately changes the curvature of the electronic device 1 to a predetermined level multiple times, to determine its reliability or endurance. With the stress-dissipating part 121, the stress between the package structure 11 and the circuit structure 10, e.g., the portion directly under the periphery region of the package structure 11, can be suppressed when the electronic device 1 is under the bending test. The possibility of the occurrence of cracks can be significantly lessened. The reliability or endurance of the electronic device 1 can thus be improved.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A electronic device, comprising:
a flexible circuit structure;
a package structure supported by the flexible circuit structure and comprising a first stress-dissipating part at a periphery region of the package structure; and
a flexible encapsulation layer encapsulating the package structure.

2. The electronic device of claim 1, wherein the package structure comprises a central region, and wherein a first distance between the central region and the flexible circuit structure is shorter than a second distance between the first stress-dissipating part and the flexible circuit structure.

3. The electronic device of claim 1, wherein the first stress-dissipating part comprises a beveled edge in a cross-sectional view.

4. The electronic device of claim 1, wherein the first stress-dissipating part has a stepped structure tapering toward the flexible circuit structure.

5. The electronic device of claim 1, wherein the package structure further comprises a substrate defining the first stress-dissipating part, a first region connected a connection element, and a second region extending from the first stress-dissipating part to the first region, and wherein a first length of the first stress-dissipating part projecting on the flexible circuit structure is greater than a second length of the second region projecting on the flexible circuit structure.

6. The electronic device of claim 1, wherein the package structure comprises an encapsulation layer defining the first stress-dissipating part and a first electronic component encapsulated by the encapsulation layer.

7. The electronic device of claim 6, wherein the package structure comprises a substrate disposed between the encapsulation layer and the flexible circuit structure, and wherein the substrate and the encapsulation layer collectively define the first stress-dissipating part.

8. The electronic device of claim 6, wherein the package structure further comprises a substrate disposed over the encapsulation layer and a second electronic component disposed over the substrate.

9. The electronic device of claim 1, wherein the package structure further comprises a second stress-dissipating part at the periphery region of the package structure, and wherein the second stress-dissipating part is geometric distinct from the first stress-dissipating part.

10. The electronic device of claim 1, wherein, in a bottom view, the first stress-dissipating part has a first edge and a second edge spaced apart from the first edge, and the first edge is non-parallel with the second edge.

11. The electronic device of claim 10, wherein, in the bottom view, the flexible circuit structure has a lateral edge substantially parallel with the second edge.

12. A electronic device, comprising:
a first region;
a second region distant from the first region; and
a package structure located in a third region between the first region and the second region,
wherein the package structure is configured to allow the first region and the second region bending toward the package structure in different extents.

13. The electronic device of claim 12, wherein the package structure comprises a first edge proximate to the first region and a second edge proximate to the second region, and a first dimension of the first edge is different from a second dimension of the second edge.

14. The electronic device of claim 12, wherein the package structure comprises a first edge proximate to the first region and a second edge proximate to the second region, and the package structure has a bottom surface, and wherein a first angle defined by the first edge and the bottom surface is different from a second angle defined by the second edge and the bottom surface.

15. The electronic device of claim 12, further comprising a circuit structure disposed under the package structure, wherein the package structure comprises a first edge proximate to the first region and a second edge proximate to the second region, and a first length of the first edge projecting on the circuit structure is different from a second length of the second edge projecting on the circuit structure.

16. A electronic device, comprising:
a circuit structure; and
a package structure disposed above the circuit structure and comprising a first periphery portion configured to dissipate stress between the package structure and the circuit structure.

17. The electronic device of claim 16, wherein the first periphery portion has a surface non-parallel to an upper surface of the circuit structure and non-perpendicular to a lateral surface of the package structure.

18. The electronic device of claim 17, wherein the package structure comprises a second periphery portion opposite to the first periphery portion and configured to dissipate stress between the package structure and the circuit structure.

19. The electronic device of claim 18, wherein the second periphery portion is asymmetrical to the first periphery portion with respect to a central line of the package structure.

20. The electronic device of claim 16, further comprising an encapsulation layer encapsulating the package structure and disposed between the package structure and the circuit structure.
